(19) United States
(12) Patent Application Publication
(10) Pub. No.: US 2026/0211010 A1
(43) Pub. Date: Jul. 23, 2026

(54) VOLTAGE SENSING SYSTEM AND MICROGRID INTERCONNECT DEVICE INCLUDING THE SAME

(71) Applicant: EATON INTELLIGENT POWER LIMITED, DUBLIN (IE)

(72) Inventors: Pratik Kumar Kar, Berhampur (IN); Mahesh Ighe, Pune (IN); Aalokkumar Dulalchandra Datta, Kolhapur (IN); Suhas Vishwanath Dhakate, Pune (IN); Akshay Ujjwal Labhe, Nagpur (IN)

(73) Assignee: EATON INTELLIGENT POWER LIMITED, DUBLIN (IE)

(21) Appl. No.: 19/032,816

(22) Filed: Jan. 21, 2025

(51) Int. Cl. G01R 19/00; H02H 9/04; H02J 3/38

(52) U.S. Cl. CPC G01R 19/0084; H02H 9/04; H02J 3/381; H02J 2101/24

(57) ABSTRACT

A voltage sensing system for use in a compact microgrid interconnect device (MID) includes a sensing component, the sensing component including grid side voltage tapping points structured to sense grid side voltages and DER side voltage tapping points structured to sense DER side voltages, and contacts attached to corresponding grid side and DER side tapping points and structured to directly contact the grid side busbar or the DER side busbar to form electrical connections between the grid side busbar and the grid side voltage tapping points and between the DER side busbar and the DER side voltage tapping points. The sensing component is structured to sensing component is structured to sense grid side voltages and frequencies via the grid side voltage tapping points and is structured to sense DER side voltages and frequencies via the DER side voltage tapping points.

### FIELD OF THE INVENTION

The disclosed concept relates generally to a power management device, and in particular, to a microgrid interconnect device including a voltage sensing system.

### BACKGROUND OF THE INVENTION

Solar energy, or photovoltaic (PV) systems coupled with energy storage systems have increasingly become an alternative to diesel generators for back-up power for single-family residences, multi-family residences, or small commercial or industrial businesses. These PV inverters, and energy storage battery inverters (collectively referred to as distributed energy resources (DERs)) are each connected to an electrical main panel, which interfaces with the utility grid (hereinafter, also referred to as the grid) and draws power from this connection to power normal loads and to charge vehicles or batteries.

A microgrid is a localized group of the DERs and loads and operate independently from the grid during the islanded mode or conjunction with the grid in the grid-connected mode. Islanding is the ability to disconnect from the grid in the event of, e.g., without limitation, a power outage while retaining the ability to manage the DERs and the loads. A microgrid interconnect device (MID) is a device structured to facilitate the connection and disconnection (islanding) of the microgrid from the grid. It ensures that the microgrid can operate in both the grid-connected and islanded modes while maintaining the safety and reliability of the electrical system. It includes a switching element such as a relay or switch, a control circuit, a communication circuit and a measurement circuit (e.g., without limitation, sensing circuit including a Rogowski coil, metering integrated chip (IC), voltage sensing and zero-crossing detection (ZCD) circuits). The MID is typically connected at the point of common coupling, which serves as a boundary between the DERs and the grid. Upon detection of a power loss, the MID disconnects the DERs from the grid and allows the DERs to supply power to the loads. Upon detection of the presence of grid power and synchronization of the voltages and frequencies of the grid and the DERs, the MID reconnects the DERs and the grid and allows both the grid and the DERs to supply power to the loads. In some examples, the DERs supply to the grid any excessive power generated by them.

Conventionally, the voltage is tapped at inputs of the grid and the DERs and the voltage tapped is brought to the measurement circuit (e.g., without limitation, a sensing circuit printed circuit board (PCB)) through wire harness. However, the conventional MIDs are large, and thus need to be installed separately from the existing load panels as illustrated in FIG. 1.

FIG. 1 illustrates an energy distribution system 2 implementing a conventional MID 200. As shown in FIG. 1, the MID 200 is installed between the existing load panel 20 and an additional load panel 30, and includes switching elements 201 connected between the existing load panel 20 and the additional load panel 30. The existing load panel 20 is connected to the grid 4 via the phase lines 12a,12b as well as a neutral (not shown) and includes a main circuit breaker 22. In some examples, the additional load panel 30 is needed to house new branch circuit breakers 25 which are to be connected to the MID 200 and the loads 7 via the load conductor 14 since the existing branch circuit breakers 25 are disconnected from the meter breaker 22 and the loads 7. In order to implement the conventional MID 200 in the energy distribution system 2, it is necessary to install additional devices such as a new load panel 30 and/or new branch circuit breakers 25 and wiring 40 as shown in FIG. 1. Such additional installations and wiring are costly and demand substantial time, resources and space that are already limited.

There is room for improvement in the power management systems, in particular the MIDs.

### SUMMARY OF THE INVENTION

In accordance with an aspect of the disclosed concept, a voltage sensing system for use in a compact microgrid interconnect device (MID) structured to be disposed in a load panel and positioned in between an electric grid and distributed energy resources (DER) connected to loads, the voltage sensing system comprises: a relay connected to a grid side busbar and a DER side busbar, the grid side busbar coupled to the grid and the DER side busbar coupled to the DERs, the relay structured to connect or disconnect the grid and the DER; a printed circuit board (PCB) including a sensing component, the sensing component including grid side voltage tapping points structured to sense grid side voltages and DER side voltage tapping points structured to sense DER side voltages; and contacts attached to corresponding grid side and DER side tapping points and structured to directly contact the grid side busbar or the DER side busbar to form electrical connections between the grid side busbar and the grid side voltage tapping points and between the DER side busbar and the DER side voltage tapping points, wherein the sensing component is structured to sensing component is structured to sense grid side voltages and frequencies via the grid side voltage tapping points and is structured to sense DER side voltages and frequencies via the DER side voltage tapping points.

In accordance with another aspect of the disclosed concept, a microgrid interconnect device (MID) structured to be disposed within a load panel between an electric grid and distributed energy resources (DER), the MID comprises: a housing; a voltage sensing system disposed within the housing including: a relay connected to a grid side busbar and a DER side busbar, the grid side busbar coupled to the grid and the DER side busbar coupled to the DER, the relay structured to connect or disconnect the grid and the DER; a printed circuit board (PCB) including a sensing component, the sensing component including grid side voltage tapping points structured to sense grid side voltages and DER side voltage tapping points structured to sense DER side voltages; and contacts attached to corresponding grid side and DER side tapping points and structured to directly contact the grid side busbar or the DER side busbar to form electrical connections between the grid side busbar and the grid side voltage tapping points and between the DER side busbar and the DER side voltage tapping points, wherein the sensing component is structured to sensing component is structured to sense grid side voltages and frequencies via the grid side voltage tapping points and is structured to sense DER side voltages and frequencies via the DER side voltage tapping points; and a control circuit disposed in the housing and structured to control the relay.

### BRIEF DESCRIPTION OF THE DRAWINGS

A full understanding of the invention can be gained from the following description of the preferred embodiments when read in conjunction with the accompanying drawings in which:

FIG. 1 illustrates a power management system including a conventional MID;

FIG. 2 illustrates an exemplary minimized MID retrofittable in conventional load panels in accordance with a non-limiting, example embodiment of the disclosed concept;

FIG. 3 illustrates the interior of the exemplary minimized MID of FIG. 2 in accordance with a non-limiting, example embodiment of the disclosed concept;

FIG. 4 illustrates a conventional load panel including an exemplary minimized MID of FIG. 2 in accordance with a non-limiting, example embodiment of the disclosed concept;

FIG. 5 is an exploded view of an exemplary voltage sensing system for use in a minimized MID in accordance with a non-limiting, example embodiment of the disclosed concept;

FIG. 6 illustrates voltage tapping points of the exemplary voltage sensing system of FIG. 5 in accordance with a non-limiting, example embodiment of the disclosed concept;

FIG. 7 is a side view of the exemplary voltage sensing system of FIG. 5 in accordance with a non-limiting, example embodiment of the disclosed concept;

FIG. 8 is a schematic diagram of the exemplary voltage sensing system of FIG. 5 in accordance with a non-limiting, example embodiment of the disclosed concept; and

FIG. 9 is a perspective view of an exemplary measurement circuit printed circuit board of the voltage sensing system of FIG. 5 in accordance with a non-limiting, example embodiment of the disclosed concept.

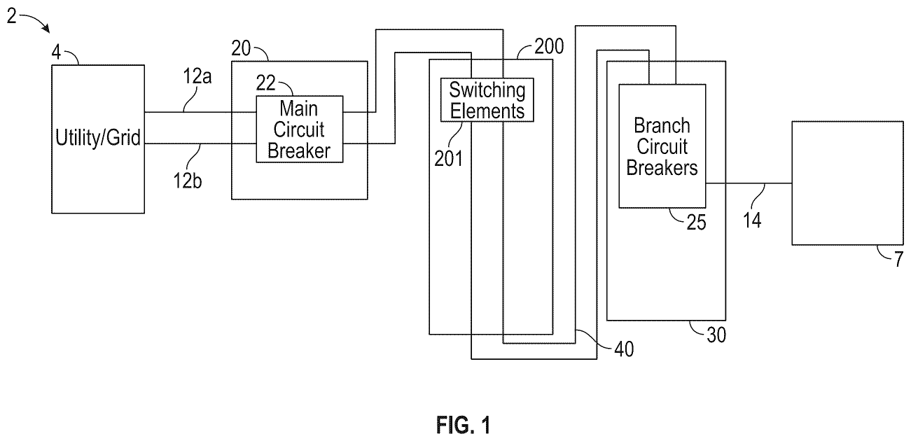

### DETAILED DESCRIPTION OF THE INVENTION:

Directional phrases used herein, such as, for example, left, right, front, back, top, bottom and derivatives thereof, relate to the orientation of the elements shown in the drawings and are not limiting upon the claims unless expressly recited therein.

As employed herein, the statement that two or more parts are “coupled” together shall mean that the parts are joined together either directly or joined through one or more intermediate parts.

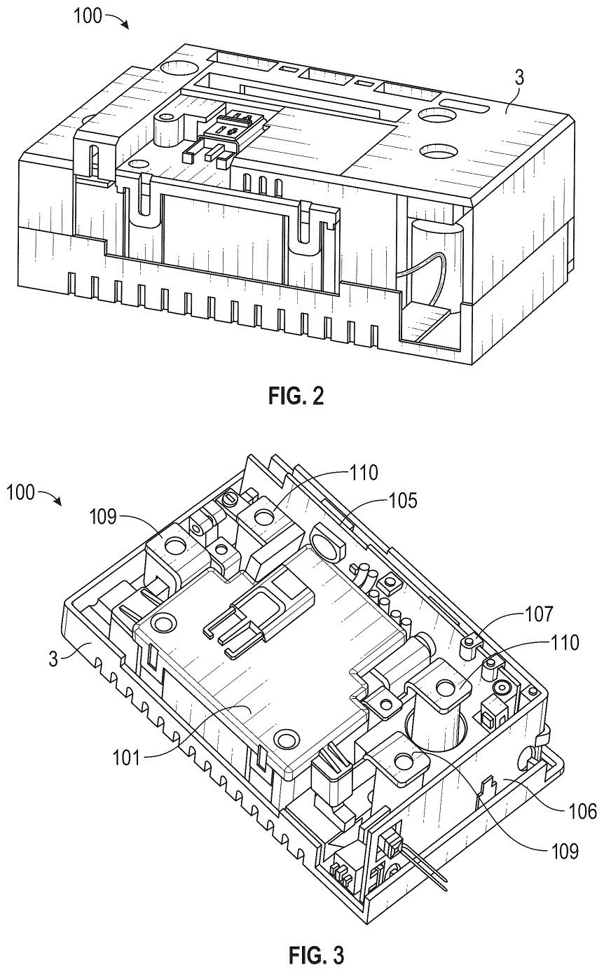

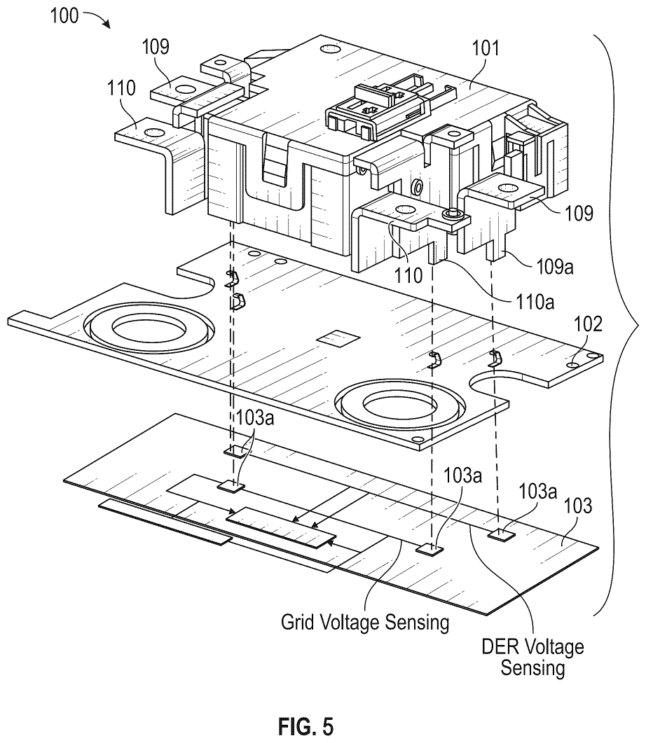

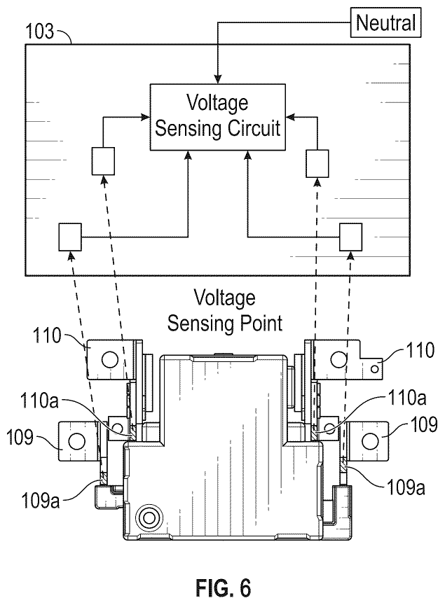

FIGS. 2-3 illustrate an exemplary minimized microgrid interconnect device (MID) 100 in accordance with a non-limiting, exemplary embodiment of the disclosed concept. The minimized MID 100 includes a housing 3 and a voltage sensing system disposed within the housing 3. The minimized MID 100 includes a relay 101, a relay driver circuit 105, a communication circuit 106, a control circuit 107, a DER side busbar 109, and a grid side busbar 110. The voltage sensing system is discussed further in detail with reference to FIGS. 5-9. The minimized MID 100 further includes a sensing component 103 and contacts 108. The sensing component 103, relay driver circuit 105, communication circuit 106, control circuit 107, and contacts 108 may be disposed on a printed circuit board (PCB) 102. In FIG. 5, the sensing component 103 is exploded out from the PCB 2 for ease of understanding the disclosed concept. However, it will be appreciated that the sensing component may be disposed on the PCB 102. The relay driver circuit 105 drives the relay 101 based on a command from the control circuit 107. The communication circuit 106 transmits and receives signals from the components of the MID 100, enabling the components to communicate with one another. The communication circuit 106 also transmits and receives signals from devices external to the MID 100, for example and without limitation, the DER 5. The control circuit 107 may be, e.g., without limitation, a microcontroller, an MCU, a processor or an integrated circuit structured to control the operation of the MID 100 and the components thereof.

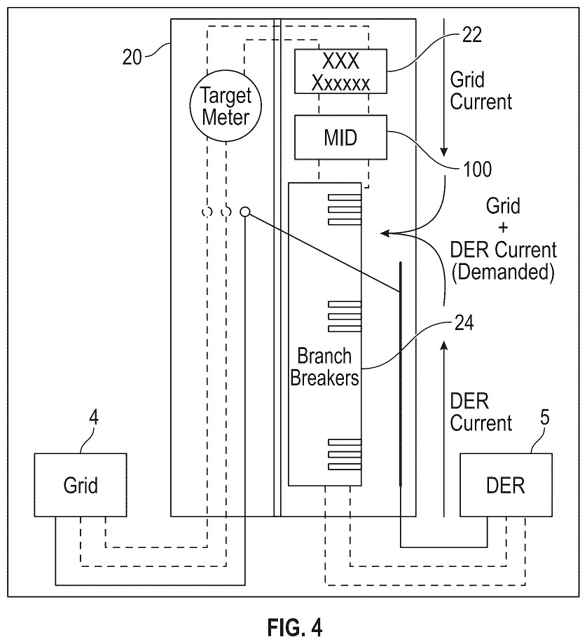

Thus, the minimized MID 100 includes all of the components of the conventional MID 200 within a much smaller and compact housing 3, which can be easily retrofitted to the conventional load panels 20 without requiring additional rewiring and wires as shown in FIG. 4.

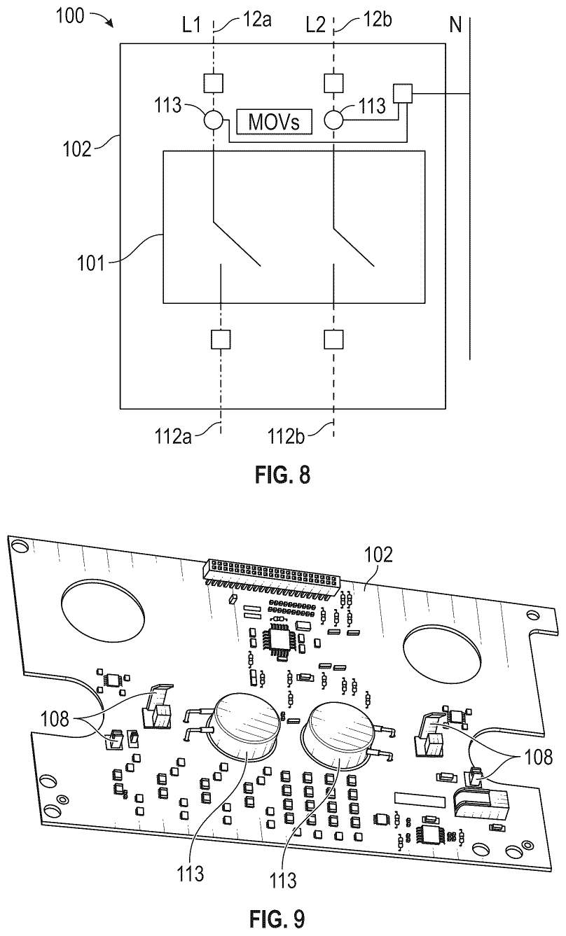

FIGS. 5-8 illustrate minimized MID 100 including the voltage sensing system in accordance with a non-limiting, exemplary embodiment of the disclosed concept. The relay 101 is connected to the DER side busbar 109 and the grid side busbar 110. The grid side busbar 110 is connected to the grid 4 via the grid lines (L1,L2) 12a,12b, and the DER line side busbar 109 is connected to the DER 5 via the DER lines (L1,L2) 112a,112b (as shown in FIG. 8). The grid side busbar 110 and the DER side busbar 109 are structured to be tapped for sensing the grid side voltages and frequencies and the DER side voltages and frequencies, respectively, by the sensing component 103. The sensing component 103 may include voltage tapping points 103a for the grid and DER side voltages and frequencies as shown in FIG. 5. Further, the sensing component 103 includes a sensing circuit connected to the voltage tapping points 103a for sensing the grid and DER side voltages and frequencies at the voltage tapping points 103a. The sensed grid and DER side voltages may be provided to the communication circuit 106 to be sent to an external device such as the DER 5 to check for synchronization.

Due to the compact size of the MID 100, the grid side busbar 110 and the DER side busbar 109 are geometrically modified to allow voltage tapping without having to install a wire harness or ring terminals. For example, the bottom ends of the grid side busbar 110 includes protrusions 110a and the DER side busbar 109 include protrusions 109a structured to electrically connect with a corresponding voltage tapping point 103a via a corresponding contact 108. Further, the busbars 109,110 also include vertical legs 109b,110b extending toward the voltage tapping points 103a such that the protrusions 109a,110a are proximate their corresponding voltage tapping point 103a and can directly contact their corresponding contact 108. That is, the grid side busbar protrusions 110a are electrically connected to corresponding voltage tapping points 103a via corresponding contacts 108 to provide a tap to sense the grid side voltages and frequencies. Similarly, the DER side busbar protrusions 109a are electrically connected to corresponding voltage tapping points 103a via corresponding contacts 108 to provide a tap to sense DER side voltages and frequencies.

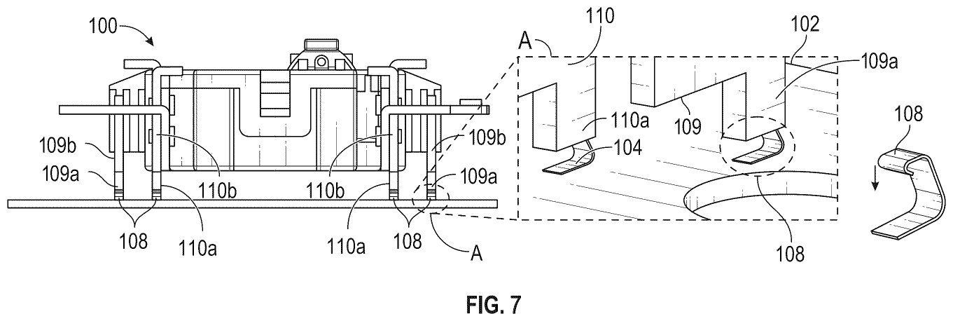

As shown in FIG. 7, the contacts 108 may be, e.g., without limitation, metal spring contacts and structured to contact the protrusions 109a,110a to provide an electrical connection between the protrusions 109a,110a and the corresponding voltage sensing point 103a. The spring contacts 108 allow tolerance for misalignments or changes in position of the busbars 109,110 with respect to the voltage sensing points 103a due to temperature changes or wear and tear.

In operation, the sensing component 103 taps line voltages from the grid 4 and the DER 5 directly at specific voltage tapping points 103a via protrusions 109a for the DER 5 and protrusions 110a for the grid 4 and senses grid side and DER side voltages and frequencies. The sensing component 103 provides the sensed grid side and DER side voltages and frequencies to the DER 5 via the communication circuit 106. The sensed grid and DER side voltages and frequencies are utilized to determine whether the grid 4 and DER 5 are synchronized. In some example embodiments, the DER 5 determines whether the grid 4 and DER 5 are synchronized utilizing the grid side and DER side voltages and frequencies sensed by the sensing component 103. If the DER 5 determines that the grid 4 and DER 5 are synchronized based on the sensed gird side and DER side voltages and frequencies, the DER 5 provides a connect command via the communication circuit 106 to the control circuit 107. In response to the connect command, the control circuit 107 operates the relay 101 via the relay driver circuit 105. More specifically, in response to the connect command, the relay 101 is closed to connect the DERs 5 and the grid 4. Then, the grid 4 and the DERs 5 simultaneously supply power to high voltage loads 7. If the DER 5 determines that the grid 4 and DER 5 are not synchronized, the DER 5 provides a disconnect command via the communication circuit 106 to the control circuit 107. In response to the disconnect command, the control circuit 107 operates the relay 101 to open via the relay driver circuit 105 to disconnect the DER 5 from the grid 4. Then, the DER 5 supplies power to the loads 7 in the islanded mode.

FIG. 8 illustrates a simplified schematic diagram of the minimized MID 100 in accordance with a non-limiting, example embodiment of the disclosed concept. In FIG. 8, the relay 101 is open and has disconnected the DER 5 from the grid 4, and thus the power distribution system is in the islanded mode. That is, the DER 5 supplies power to the loads 7 in the islanded mode. Further, a common surge protection device, e.g., without limitation, metal oxide varistors (MOVs) 113, are connected to the relay 101 and structured to protect the minimized MID 100 and the power distribution system from transient voltage surges from the grid 4 and the DER 5. Further, the relay 101 provides the galvanic isolation between the grid 4 and the DER 5. The galvanic isolation prevents voltages or currents from flowing back into the grid 4 during outages, allows the microgrid to stabilize the DER voltage and frequency without interference from the grid 4, and minimizes the noise or transients from the grid 4 to sensitive DER equipment (e.g., without limitation, inverters).

FIG. 9 illustrates an exemplary PCB 102 of the minimized MID 100 in accordance with a non-limiting, example embodiment of the disclosed concept. As shown in FIG. 9, the contacts 108 are attached at corresponding voltage tapping points. The PCB 102 also includes MOVs 113 for protection against the transient voltage surge. The MOVs 113 are structured to provide common surge protection against transient high grid or DER voltages.

By minimizing and placing the required components of the microgrid interconnect devices in a compact housing 3, the MID 100 can be easily retrofit in the existing, field installed load panels without having to install additional panels and components and require significant rewiring. In response to the space constraints within the minimized MID 100, the voltage sensing system provides a compact architecture in a minimally vertically-spaced alignment so as to place protrusions 109a,110a of busbars 109,110 in close proximity to corresponding voltage tapping points 103a. Such an arrangement allows voltage tapping of the busbars 109,110 without any wire harness, thereby eliminating any inductive or capacitive noises from the wire harness, and thus significantly increasing voltage sensing accuracy. Further, the minimally vertically-spaced alignment simplifies the assembly and removes additional steps (e.g., without limitation, installing ring terminals and the wire harness) that are required by the conventional MIDs 200 for voltage tapping. In addition, the voltage sensing system utilizes the spring connectors 108, which provides additional tolerance in the assembly. Furthermore, by modifying the geometry of the grid and DER side busbars 109,110, the voltage sensing system allows for even more compact alignment among the components. Therefore, as compared to the conventional MID 200, the minimized MID 100 voltage sensing system significantly improves the voltage sensing accuracy, removes the need to install additional, cumbersome panels and rewiring, simplifies the MID assembly and installation process, and reduces the manufacturing and installation costs.

While specific embodiments of the invention have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of disclosed concept which is to be given the full breadth of the claims appended and any and all equivalents thereof.

What is claimed is:

1. A voltage sensing system for use in a compact microgrid interconnect device (MID) structured to be disposed in a load panel and positioned in between an electric grid and distributed energy resources (DER) connected to loads, the voltage sensing system comprising:
a relay connected to a grid side busbar and a DER side busbar, the grid side busbar coupled to the grid and the DER side busbar coupled to the DERs, the relay structured to connect or disconnect the grid and the DER;
a printed circuit board (PCB) including a sensing component, the sensing component including grid side voltage tapping points structured to sense grid side voltages and DER side voltage tapping points structured to sense DER side voltages; and
contacts attached to corresponding grid side and DER side tapping points and structured to directly contact the grid side busbar or the DER side busbar to form electrical connections between the grid side busbar and the grid side voltage tapping points and between the DER side busbar and the DER side voltage tapping points,
wherein the sensing component is structured to sensing component is structured to sense grid side voltages and frequencies via the grid side voltage tapping points and is structured to sense DER side voltages and frequencies via the DER side voltage tapping points.

2. The voltage sensing system of claim 1, further comprising:
a control circuit structured to control the relay; and
a communication circuit structured to communicate with the sensing component, the control circuit, and the DER,
wherein the sensing component is structured to provide the sensed grid and DER side voltages and frequencies to the DER.

3. The voltage sensing system of claim 2, wherein the DER is structured to determine whether the grid and DER are synchronized based on the sensed grid and DER side voltages and frequencies.

4. The voltage sensing system of claim 3, wherein the DER is structured to provide a connect signal to the control circuit via the communication circuit in response to determining that the grid and DER are synchronized, and wherein the control circuit is structured to control the relay to close to connect the DER and the grid in response to the connect signal.

5. The voltage sensing system of claim 4, wherein the DER is structured to provide a disconnect signal to the control circuit via the communication circuit in response to determining that the grid and DER are not synchronized, and wherein the control circuit is structured to control the relay to open to disconnect the DER from the grid in response to the disconnect signal.

6. The voltage sensing system of claim 1, wherein the grid side voltage tapping points are electrically connected to the grid side busbar and the DER side voltage tapping points are electrically connected to the line side busbar without a wire harness.

7. The voltage sensing system of claim 1, wherein grid side busbar includes a number of protrusions, wherein the DER side busbar includes a number of protrusions, wherein the grid side voltage tapping points are located proximate to corresponding protrusions of the grid side busbar, and wherein DER side voltage tapping points are located proximate to corresponding protrusions of the DER side busbar.

8. The voltage sensing system of claim 7, wherein the contacts are disposed between each protrusion of the grid and DER side busbars and corresponding grid and DER voltage tapping points.

9. The voltage sensing system of claim 1, wherein the contacts are spring contacts.

10. The voltage sensing system of claim 1, further comprising:
a voltage surge protection device disposed on the PCB and connected to the grid and the DER.

11. The voltage sensing system of claim 10, wherein the voltage surge protection device is metal oxide varistors (MOVs) structured to provide common surge protection against transient high grid or DER voltages.

12. The voltage sensing system of claim 1, wherein the relay provides galvanic isolation between the grid and the DER.

13. A microgrid interconnect device (MID) structured to be disposed within a load panel between an electric grid and distributed energy resources (DER), the MID comprising:
a housing;
a voltage sensing system disposed within the housing including:
a relay connected to a grid side busbar and a DER side busbar, the grid side busbar coupled to the grid and the DER side busbar coupled to the DER, the relay structured to connect or disconnect the grid and the DER;
a printed circuit board (PCB) including a sensing component, the sensing component including grid side voltage tapping points structured to sense grid side voltages and DER side voltage tapping points structured to sense DER side voltages; and
contacts attached to corresponding grid side and DER side tapping points and structured to directly contact the grid side busbar or the DER side busbar to form electrical connections between the grid side busbar and the grid side voltage tapping points and between the DER side busbar and the DER side voltage tapping points,
wherein the sensing component is structured to sensing component is structured to sense grid side voltages and frequencies via the grid side voltage tapping points and is structured to sense DER side voltages and frequencies via the DER side voltage tapping points; and
a control circuit disposed in the housing and structured to control the relay.

14. The MID of claim 13, further comprising:
a communication circuit structured to communicate with the sensing component, the control circuit, and the DER,
wherein the sensing component is structured to provide the sensed grid and DER side voltages and frequencies to the DER.

15. The MID of claim 14, wherein the DER is structured to determine whether the grid and DER are synchronized based on the sensed grid and DER side voltages and frequencies.

16. The MID of claim 15, wherein the DER is structured to provide a connect signal to the control circuit via the communication circuit in response to determining that the grid and DER are synchronized, and wherein the control circuit is structured to control the relay to close to connect the DER and the grid in response to the connect signal.

17. The MID of claim 15, wherein the DER is structured to provide a disconnect signal to the control circuit via the communication circuit in response to determining that the grid and DER are not synchronized, and wherein the control circuit is structured to control the relay to open to disconnect the DER from the grid in response to the disconnect signal.

18. The MID of claim 13, wherein the grid side voltage tapping points are electrically connected to the grid side busbar and the DER side voltage tapping points are electrically connected to the line side busbar without a wire harness.

19. The MID of claim 13, wherein grid side busbar includes a number of protrusions, wherein the DER side busbar includes a number of protrusions, wherein the grid side voltage tapping points are located proximate to corresponding protrusions of the grid side busbar, and wherein DER side voltage tapping points are located proximate to corresponding protrusions of the DER side busbar.

20. The MID of claim 19, wherein the contacts are disposed between each protrusion of the grid and DER side busbars and corresponding grid and DER voltage tapping points.
